(19) United States
(12) Patent Application Publication
(10) Pub. No.: US 2013/0095431 A1
(43) Pub. Date: Apr. 18, 2013

(54) FABRICATING METHOD FOR CONTROLLING HOLE-WALL ANGLE OF CONTACT HOLE IN LCD DEVICE

(71) Applicants: Jo-shan Wu, Shenzhen (CN); Hsiao-hsien Chen, Shenzhen (CN)

(72) Inventors: Jo-shan Wu, Shenzhen (CN); Hsiao-hsien Chen, Shenzhen (CN)

(73) Assignee: Shenzhen China Star Optoelectronics Technology Co., Ltd., Shenzhen, Guangdong (CN)

(21) Appl. No.: 13/377,543

(22) PCT Filed: Nov. 16, 2011
(86) PCT No.: PCT/CN2011/082285

§ 371 Date: Dec. 10, 2011

(30) Foreign Application Priority Data
Oct. 17, 2011 (CN) 201110315023.8
Nov. 16, 2011 (CN) PCT/CN2011/082285

(51) Int. Cl. G03F 7/20

(52) U.S. Cl. 430/320

(57) ABSTRACT

A fabricating method for controlling a hole-wall angle of a contact hole in a liquid crystal display (LCD) device is disclosed, which comprises the following steps of: A) applying a photoresist on a substrate to form a photoresist layer; B) exposing the photoresist layer by using a photo-hardening monomer of a predetermined pattern; and C) using a developer to develop the photoresist layer to obtain a hole-wall having a preset angle of the contact hole by controlling a development duration, a development temperature and a concentration of the developer. The present disclosure accurately controls the hole-wall inclination angle of the contact hole to range between 45° and 70° by means of the melting point characteristics of the photoresist comprising a photo-hardening monomer.

### BACKGROUND

1. Technical Field

The present disclosure relates to the field of liquid crystal displaying, and more particularly, to a fabricating method for controlling a hole-wall angle of a contact hole in a liquid crystal display (LCD) device.

2. Description of Related Art

FIG. 1 is a cross-sectional view of a prior art LCD panel. Referring to FIG. 1, the LCD panel comprises a thin film transistor (TFT) substrate 60, a color filter (CF) substrate 70 opposite to the TFT substrate 60, and a liquid crystal layer 80 sandwiched between the TFT substrate 60 and the CF substrate 70.

The TFT substrate 60 comprises a first substrate 10, TFTs 20 formed on the first substrate 10, an organic insulation layer 30 formed on the first substrate 10 formed with the TFTs 20, pixel electrodes 40 formed on the organic insulation layer 30 and a first alignment film 50 formed on the pixel electrodes 40.

Each of the TFTs 20 comprises a gate 21, a gate insulation layer 22, an active pattern 23, an ohmic contact pattern 24, a source 25 and a drain 26. The gate 21 is insulated from the source 25 and the drain 26 by means of the gate insulation layer 22. The active pattern 23 and the ohmic contact pattern 24 are formed on the gate insulation layer 22 to electrically connect the source 25 with the drain 26 according to a power source applied to the gate 21. The source 25 and the drain 26 are formed on the active pattern 23 and the ohmic contact pattern 24.

The organic insulation layer 30 is formed on the TFTs 20. Contact holes 35 for exposing the drains 26 are formed on the organic insulation layer 30, and a hole-wall of each of the contact holes 35 has an inclination angle 0. The pixel electrodes 40 are formed uniformly on the organic insulation layer 30, the drains 26 exposed through the contact holes 35 and sidewalls of the contact holes 35. The first alignment film 50 is formed on the pixel electrodes 40 and comprises a plurality of alignment grooves extending in a predetermined direction or a rubbing direction.

The CF substrate 70 comprises a second substrate 71, a color filter 72, a common electrode 73 and a second alignment film 74. The common electrode 73 faces towards the pixel electrodes 40 and is opposite to the TFT substrate 60. The CF substrate 70 and the TFT substrate 60 are assembled together facing towards each other with the liquid crystal layer 80 being sandwiched therebetween.

Currently, a conventional method of fabricating the contact holes 35 is as follows:

(1) forming the organic insulation layer 30 of an insulation material on the first substrate 10 through sputtering;

(2) applying a photoresist on the organic insulation layer 30;

(3) patterning the photoresist layer by using a mask to expose and develop the photoresist layer;

(4) etching the mask by using a photoresist pattern and then carrying out a photoresist edge removing process to remove a portion of the photoresist; and

(5) hardening the mask through baking to obtain the contact holes 35.

In the conventional fabricating method described above, the hole-wall inclination angle of the contact holes is formed through baking, so it is difficult to accurately control the angle of the contact holes 35. Specifically, if the hole-wall inclination angle of the contact holes 35 is smaller than 45°, the aperture ratio and consequently the luminance will be decreased due to a too large area of each of the contact holes 35; and if the hole-wall inclination angle of the contact holes 35 is greater than 70°, a nonuniform plated film will be caused in a next indium tin oxide (ITO) process.

### BRIEF SUMMARY

The primary objective of the present disclosure is to provide a fabricating method for controlling a hole-wall angle of a contact hole in an LCD device, which can control the hole-wall inclination angle of the contact hole to range between 45° and 70° so as to deliver an optimal aperture ratio.

To achieve the aforesaid objective, the present disclosure provides a fabricating method for controlling a hole-wall angle of a contact hole in an LCD device, which comprises the following steps of:

A) applying a photoresist on a substrate to form a photoresist layer;

B) exposing the photoresist layer by using a photo-hardening monomer of a predetermined pattern;

C) using a developer to develop the photoresist layer to obtain a hole-wall having a preset angle of the contact hole by controlling a development duration, a development temperature and a concentration of the developer.

Preferably, the step C) comprises: forming the hole-wall having the preset angle of the contact hole by keeping the concentration of the developer and the development temperature unchanged but controlling the development duration.

Preferably, the development duration ranges between 30 seconds (s) and 40 s.

Preferably, the step C) comprises:

forming the hole-wall having the preset angle of the contact hole by keeping the development duration and the development temperature unchanged but controlling the concentration of the developer.

Preferably, the concentration of the developer ranges between 0.03% and 0.05%.

Preferably, the step C) comprises:

forming the hole-wall having the preset angle of the contact hole by keeping the concentration of the developer and the development duration unchanged but controlling the development temperature.

Preferably, the development temperature ranges between 20° C. and 40° C.

Preferably, the method further comprises the following step after the step C):

D) hardening the photo-hardening monomer by using an ultraviolet (UV) light to irradiate the photoresist layer.

The present disclosure further provides a fabricating method for controlling a hole-wall angle of a contact hole in an LCD device, which comprises the following steps of:

A) removing moisture from a substrate through baking in advance, applying hexamethyl disilazane (HMDS) through a gas assisted process, applying a photoresist layer through a spin coating process, and then pre-baking the photoresist layer;

B) exposing the photoresist layer by using a photomask, wherein protons are generated by a photo-acid generator (PAG) in the photoresist layer when being exposed to light irradiation so that exposed portions of the photoresist are solved by a developer to define a contact hole pattern;

C) using a developer to develop the photoresist layer to obtain a hole-wall having a preset angle of the contact hole by controlling a development duration, a development temperature and a concentration of the developer.

Preferably, the step C) comprises:

forming the hole-wall having the preset angle of the contact hole by keeping the concentration of the developer and the development temperature unchanged but controlling the development duration.

Preferably, the development duration ranges between 30 s and 40 s.

Preferably, the step C) comprises:

forming the hole-wall having the preset angle of the contact hole by keeping the development duration and the development temperature unchanged but controlling the concentration of the developer.

Preferably, the concentration of the developer ranges between 0.03% and 0.05%.

Preferably, the step C) comprises:

forming the hole-wall having the preset angle of the contact hole by keeping the concentration of the developer and the development duration unchanged but controlling the development temperature.

Preferably, the development temperature ranges between 20° C. and 40° C.

Preferably, the method further comprises the following step after the step C):

D) hardening the photo-hardening monomer by using a UV light to irradiate the photoresist layer.

As compared with the prior art method that controls a hole-wall angle of a contact hole by controlling a post-baking temperature, the fabricating method for controlling a hole-wall angle of a contact hole in an LCD device according to the present disclosure can accurately control the hole-wall inclination angle of the contact hole to range between 45° and 70° by means of the melting point characteristics of the photoresist comprising a photo-hardening monomer and by comprehensively controlling the development temperature, the concentration of the developer and the development duration.

### BRIEF DESCRIPTION OF THE DRAWINGS

FIG. 1 is a cross-sectional view of a prior art LCD panel;

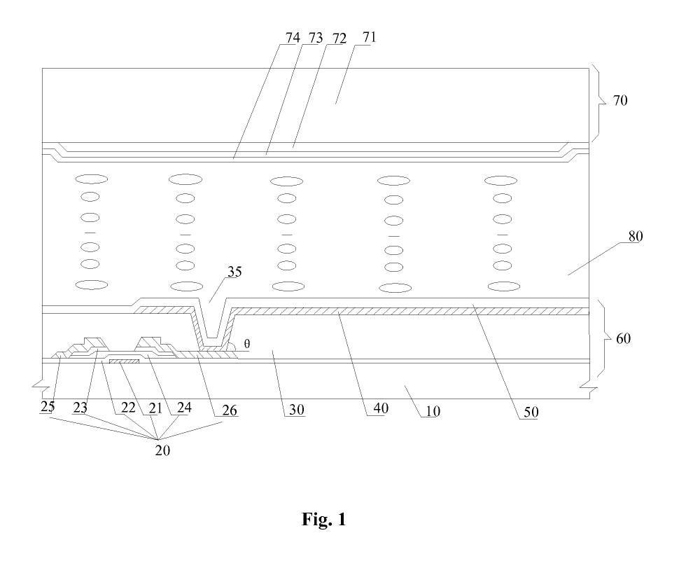

FIG. 2 is a schematic flowchart diagram of an embodiment of a fabricating method for controlling a hole-wall angle of a contact hole in an LCD device according to the present disclosure;

FIG. 3 is a graph illustrating the hole-wall angle of the contact hole and a development duration in the embodiment of the fabricating method for controlling a hole-wall angle of a contact hole in an LCD device according to the present disclosure;

FIG. 4 is a graph illustrating the hole-wall angle of the contact hole and a concentration of a developer in the embodiment of the fabricating method for controlling a hole-wall angle of a contact hole in an LCD device according to the present disclosure; and

FIG. 5 is a graph illustrating the hole-wall angle of the contact hole and a development temperature in the embodiment of the fabricating method for controlling a hole-wall angle of a contact hole in an LCD device according to the present disclosure.

Hereinafter, implementations, functional features and advantages of the present disclosure will be further described with reference to embodiments thereof and the attached drawings.

### DETAILED DESCRIPTION

It shall be understood that, the embodiments described herein are only intended to illustrate but not to limit the present disclosure.

As is well known, a photoresist is a photosensitive material that is temporarily coated on a wafer; and similar to a negative photosensitive material, the photoresist undergoes a chemical reaction after being irradiated so as to transfer an optical pattern on a photomask onto a surface of the wafer. During formation of a contact hole pattern, a positive photoresist is generally adopted because the contact hole pattern has a high requirement on the resolution. This photoresist is usually novolac that is cross-linked through a photosensitizer. During exposure, photons initiate a photochemical reaction of a photo-acid generator (PAG) in the photoresist to generate protons H⁺ (a photo acid). The protons react with the photoresist; and this fractures correlation bonds of the photoresist and thus retrocross-links the photoresist so that exposed portions of the photoresist can be solved by a developer, thereby obtaining a photoresist pattern.

According to the present disclosure, the hole-wall angle of the contact hole can be accurately controlled to be an exact preset value by comprehensively controlling the concentration of the developer, the development duration and the development temperature in the development process.

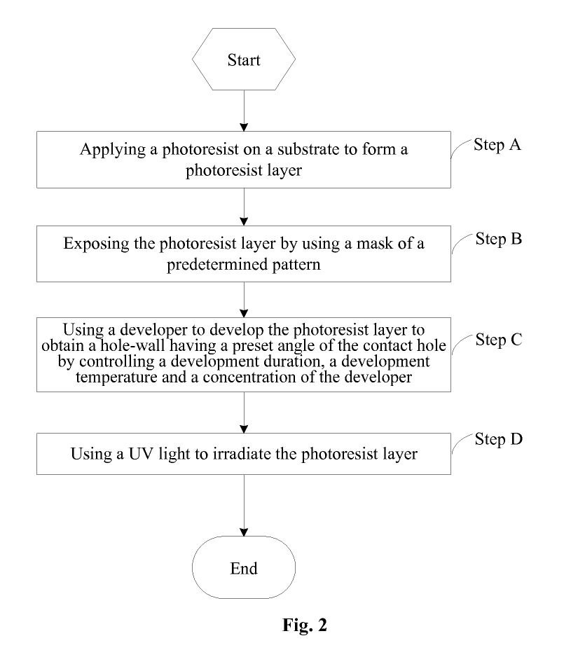

As shown in FIG. 2, an embodiment of a fabricating method for controlling a hole-wall angle of a contact hole in an LCD device according to the present disclosure comprises steps A), B) and C).

A) Applying a photoresist on a substrate to form a photoresist layer.

Firstly, the photoresist layer is coated on the substrate. The photoresist layer may have a thickness ranging from 500 nm to 10,000 nm. The photoresist layer comprises a photo-hardening monomer so as to be exposed to define a contact hole pattern. Specifically, moisture is removed from the substrate through baking in advance; then, hexamethyl disilazane (HMDS) is applied through a gas assisted process in which an assistant gas is used to spray methyl silicon-nitrogen compounds to a surface of the substrate; thereafter, the photoresist layer (e.g., a novolac photoresist) is applied through a spin coating process; and then the photoresist layer is pre-baked to remove excessive solvent from the photoresist so as to harden the photoresist and enhance the adhesion between the photoresist and the substrate.

B) Exposing the photoresist layer by using a mask of a predetermined pattern.

The photoresist layer is exposed by using a photomask. Protons are generated by a photo-acid generator (PAG) in the photoresist layer when being exposed to light irradiation so that exposed portions of the photoresist are solved by a developer to define the contact hole pattern.

C) Using a developer to develop the photoresist layer to obtain a hole-wall having a preset angle of the contact hole by controlling a development duration, a development temperature and a concentration of the developer.

After the exposure process is completed, the development process is carried out by using the developer (e.g., tetramethylammonium hydroxide (TMAH)) to solve portions of the photoresist that are retrocross-linked due to the reaction between the photoresist and the protons while portions of the photoresist that are not completely retrocross-linked in the exposure region are maintained. In this way, the contact hole pattern is obtained on the photoresist layer.

In the step C), the hole-wall inclination angle of the contact hole is accurately controlled by comprehensively controlling the concentration of the developer, the development duration and the development temperature. This can be accomplished in the following three ways.

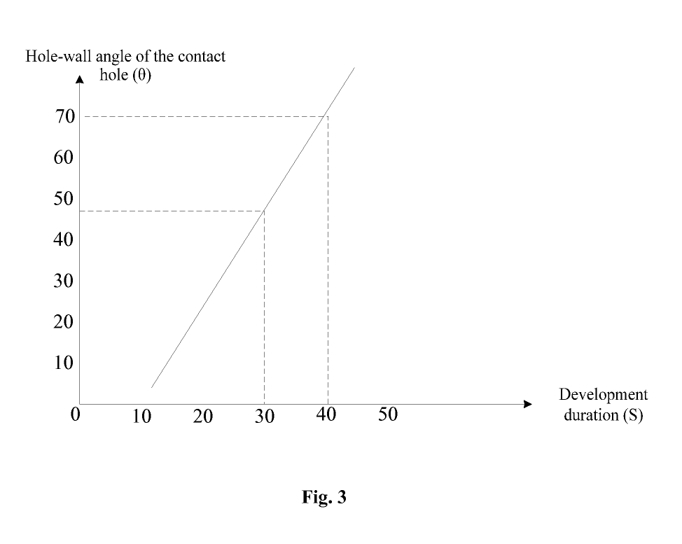

(1) The hole-wall inclination angle of the contact hole can be controlled by keeping the concentration of the developer and the development temperature unchanged but changing the development duration. Referring to FIG. 3, there is shown a graph illustrating the development duration and the hole-wall inclination angle of the contact hole when the concentration of the developer and the development temperature are kept unchanged. As can be seen from FIG. 3, the longer the development duration (i.e., the duration when the developer is soaked) is, the stronger the power of the development reaction will be and the more prominent the development reaction at sides of the contact hole will be. When the development duration is 30 seconds (s), the hole-wall inclination angle of the contact hole is about 45°; and when the development duration is 40 s, the hole-wall inclination angle of the contact hole is about 70°.

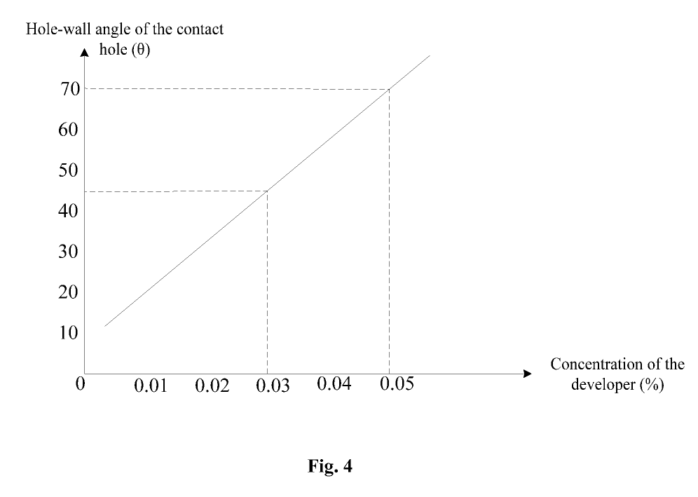

(2) The hole-wall inclination angle of the contact hole can be controlled by keeping the development duration and the development temperature unchanged but changing the concentration of the developer. Referring to FIG. 4, there is shown a graph illustrating the concentration of the developer and the hole-wall inclination angle of the contact hole when the development duration and the development temperature are kept unchanged. As can be seen from FIG. 4, the higher the concentration of the developer is, the stronger the power of the development reaction will be. The developer of a high concentration makes a vertical development rate in the contact hole larger than a development rate at the sides of the contact hole. When the concentration of the developer is 0.03%, the hole-wall inclination angle of the contact hole is about 45°; and when the concentration of the developer is 0.05%, the hole-wall inclination angle of the contact hole is about 70°.

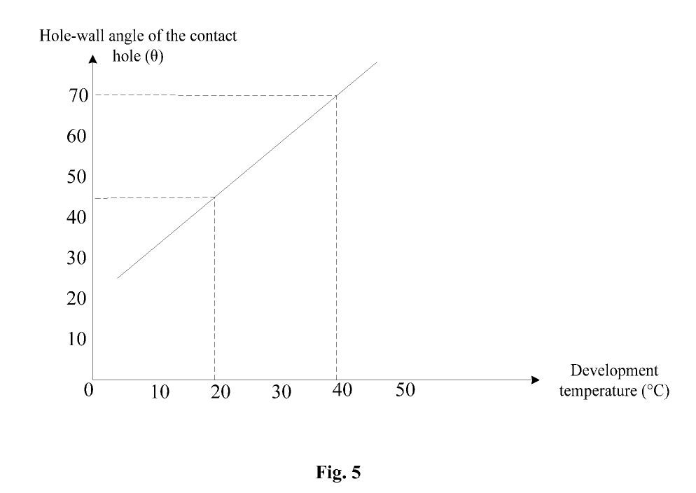

(3) The hole-wall inclination angle of the contact hole can be controlled by keeping the development duration and the concentration of the developer unchanged but changing the development temperature. Referring to FIG. 5, there is shown a graph illustrating the development temperature and the hole-wall inclination angle of the contact hole when the development duration and the concentration of the developer are kept unchanged. As can be seen from FIG. 5, the higher the development temperature is, the stronger the power of the development reaction will be. The developer of a high temperature makes a vertical development rate in the contact hole larger than a development rate at the sides of the contact hole. When the development temperature is 20° C., the hole-wall inclination angle of the contact hole is about 45°; and when the development temperature is 40° C., the hole-wall inclination angle of the contact hole is about 70°.

As compared with the prior art method that controls a hole-wall angle of a contact hole by controlling a post-baking temperature, the fabricating method for controlling a hole-wall angle of a contact hole in an LCD device according to this embodiment can accurately control the hole-wall inclination angle of the contact hole to range between 45° and 70° by means of the melting point characteristics of the photoresist comprising a photo-hardening monomer.

Further, in order to form the contact hole pattern after being developed, a step D) of exposing the photoresist layer for the second time is executed. This step is executed by using an ultraviolet (UV) light to irradiate the photoresist layer to harden the photo-hardening monomer.

What described above are only preferred embodiments of the present disclosure but are not intended to limit the scope of the present disclosure. Accordingly, any equivalent structural or process flow modifications that are made on basis of the specification and the attached drawings or any direct or indirect applications in other technical fields shall also fall within the scope of the present disclosure.

What is claimed is:

1. A fabricating method for controlling a hole-wall angle of a contact hole in a liquid crystal display (LCD) device, comprising the following steps of:
A) applying a photoresist on a substrate to form a photoresist layer;
B) exposing the photoresist layer by using a photo-hardening monomer of a predetermined pattern; and
C) using a developer to develop the photoresist layer to obtain a hole-wall having a preset angle of the contact hole by controlling a development duration, a development temperature and a concentration of the developer.

2. The method of claim 1, wherein the step C) comprises:
forming the hole-wall having the preset angle of the contact hole by keeping the concentration of the developer and the development temperature unchanged but controlling the development duration.

3. The method of claim 2, wherein the development duration ranges between 30 seconds (s) and 40 s.

4. The method of claim 1, wherein the step C) comprises:
forming the hole-wall having the preset angle of the contact hole by keeping the development duration and the development temperature unchanged but controlling the concentration of the developer.

5. The method of claim 4, wherein the concentration of the developer ranges between 0.03% and 0.05%.

6. The method of claim 1, wherein the step C) comprises:
forming the hole-wall having the preset angle of the contact hole by keeping the concentration of the developer and the development duration unchanged but controlling the development temperature.

7. The method of claim 6, wherein the development temperature ranges between 20° C. and 40° C.

8. The method of claim 1, further comprising the following step after the step C):
D) hardening the photo-hardening monomer by using an ultraviolet (UV) light to irradiate the photoresist layer.

9. The method of claim 2, further comprising the following step after the step C):
D) hardening the photo-hardening monomer by using a UV light to irradiate the photoresist layer.

10. The method of claim 4, further comprising the following step after the step C):
D) hardening the photo-hardening monomer by using a UV light to irradiate the photoresist layer.

11. A fabricating method for controlling a hole-wall angle of a contact hole in an LCD device, comprising the following steps of:
A) removing moisture from a substrate through baking in advance, applying hexamethyl disilazane (HMDS) through a gas assisted process, applying a photoresist layer through a spin coating process, and then pre-baking the photoresist layer;
B) exposing the photoresist layer by using a photomask, wherein protons are generated by a photo-acid generator (PAG) in the photoresist layer when being exposed to light irradiation so that exposed portions of the photoresist are solved by a developer to define a contact hole pattern; and
C) using a developer to develop the photoresist layer to obtain a hole-wall having a preset angle of the contact hole by controlling a development duration, a development temperature and a concentration of the developer.

12. The method of claim 11, wherein the step C) comprises:
forming the hole-wall having the preset angle of the contact hole by keeping the concentration of the developer and the development temperature unchanged but controlling the development duration.

13. The method of claim 12, wherein the development duration ranges between 30 s and 40 s.

14. The method of claim 11, wherein the step C) comprises:
forming the hole-wall having the preset angle of the contact hole by keeping the development duration and the development temperature unchanged but controlling the concentration of the developer.

15. The method of claim 14, wherein the concentration of the developer ranges between 0.03% and 0.05%.

16. The method of claim 11, wherein the step C) comprises:
forming the hole-wall having the preset angle of the contact hole by keeping the concentration of the developer and the development duration unchanged but controlling the development temperature.

17. The method of claim 16, wherein the development temperature ranges between 20° C. and 40° C.

18. The method of claim 11, further comprising the following step after the step C):
D) hardening the photo-hardening monomer by using a UV light to irradiate the photoresist layer.

19. The method of claim 12, further comprising the following step after the step C):
D) hardening the photo-hardening monomer by using a UV light to irradiate the photoresist layer.

20. The method of claim 14, further comprising the following step after the step C):
D) hardening the photo-hardening monomer by using a UV light to irradiate the photoresist layer.
